(19) United States
(12) Patent Application Publication
(10) Pub. No.: US 2025/0218693 A1
(43) Pub. Date: Jul. 3, 2025

(54) CAPACITOR STRUCTURE AND MANUFACTURING METHOD THEREOF

(71) Applicant: United Microelectronics Corp., Hsinchu (TW)

(72) Inventors: Yao-Hsien Chung, Tainan City (TW); Fu-Yu Tsai, Tainan City (TW); Bin-Siang Tsai, Changhua County (TW)

(73) Assignee: United Microelectronics Corp., Hsinchu (TW)

(21) Appl. No.: 18/433,437

(22) Filed: Feb. 6, 2024

(30) Foreign Application Priority Data
Dec. 28, 2023 (TW) 112151452

(51) Int. Cl. H01G 4/33; H01G 4/30

(52) U.S. Cl. CPC H01G 4/33; H01G 4/306

(57) ABSTRACT

Disclosed is a capacitor structure including a substrate, a stack structure, and a capacitor. The stack structure includes at least one first dielectric layer and at least one second dielectric layer alternately disposed on the substrate. There is a trench in the at least one first dielectric layer, the at least one second dielectric layer, and the substrate. The trench has at least one recess on at least one sidewall of the at least one first dielectric layer. The capacitor is disposed on a surface of the trench.

### CROSS-REFERENCE TO RELATED APPLICATION

This application claims the priority benefit of Taiwan application serial no. 112151452, filed on Dec. 28, 2023. The entirety of the above-mentioned patent application is hereby incorporated by reference herein and made a part of this specification.

### BACKGROUND

### Field of the Disclosure

The present disclosure relates to a semiconductor structure and a manufacturing method thereof, and in particular, to a capacitor structure and a manufacturing method thereof.

### Description of Related Art

A capacitor is a semiconductor component commonly used in electronic products. However, how to further improve the capacitance value of the capacitor structure and reduce the process complexity of the capacitor structure are the goals to be attained with continuous efforts.

### SUMMARY OF THE DISCLOSURE

The present disclosure provides a capacitor structure and a manufacturing method thereof, which may further increase the capacitance value of the capacitor structure and reduce the process complexity of the capacitor structure.

The present disclosure provides a capacitor structure, including a substrate, a stack structure and a capacitor. The stack structure includes at least one first dielectric layer and at least one second dielectric layer alternately disposed on the substrate. There is a trench in the at least one first dielectric layer, the at least one second dielectric layer and the substrate. The trench has at least one recess on the at least one sidewall of the at least one first dielectric layer. The capacitor is disposed on the surface of the trench.

According to an embodiment of the present disclosure, in the capacitor structure, the cross-sectional contour of the at least one recess may include a curved surface.

According to an embodiment of the present disclosure, in the capacitor structure, the trench does not have a recess on the sidewall of the substrate.

According to an embodiment of the present disclosure, in the capacitor structure, the sidewall of the substrate exposed by the trench may be a flat surface.

According to an embodiment of the present disclosure, in the capacitor structure, the trench does not have a recess on the at least one sidewall of the at least one second dielectric layer.

According to an embodiment of the present disclosure, in the capacitor structure, the at least one sidewall of the at least one second dielectric layer exposed by the trench may be a flat surface.

According to an embodiment of the present disclosure, in the capacitor structure, the first dielectric layer closest to the substrate may be located between the second dielectric layer closest to the substrate and the substrate.

According to an embodiment of the present disclosure, in the capacitor structure, the second dielectric layer closest to the substrate may be located between the first dielectric layer closest to the substrate and the substrate.

According to an embodiment of the present disclosure, in the capacitor structure, the capacitor may be further disposed on the top surface of the stack structure.

According to an embodiment of the present disclosure, the capacitor structure may further include a third dielectric layer and a fourth dielectric layer. The third dielectric layer is disposed between the capacitor and the substrate and between the capacitor and the stack structure. The fourth dielectric layer is disposed on the capacitor. The fourth dielectric layer may be filled in the trench.

The present disclosure provides a manufacturing method of a capacitor structure, which includes the following steps: providing a substrate; forming a stack structure, wherein the stack structure includes at least one first dielectric layer and at least one second dielectric layer alternately disposed on the substrate; forming a trench in the at least one first dielectric layer, the at least one second dielectric layer, and the substrate, wherein the trench has at least one recess on at least one sidewall of the at least one first dielectric layer; and forming a capacitor on a surface of the trench.

According to an embodiment of the present disclosure, in the method for manufacturing a capacitor structure, the method for forming a trench may include the following steps: forming a patterned photoresist layer on the stack structure; using the patterned photoresist layer as a mask to remove a part of the stack structure and a part of the substrate to form a trench.

According to an embodiment of the present disclosure, in the manufacturing method of the capacitor structure, the method for removing a part of the stack structure and a part of the substrate is, for example, dry etching.

According to an embodiment of the present disclosure, the manufacturing method of the capacitor structure may further include the following steps: removing the patterned photoresist layer after forming the trench.

According to an embodiment of the present disclosure, in the manufacturing method of the capacitor structure, the method of forming the at least one recess may include the following steps: performing an isotropic etching process on the at least one first dielectric layer to form the at least one recess.

According to an embodiment of the present disclosure, in the manufacturing method of the capacitor structure, the isotropic etching process is, for example, a dry etching process or a wet etching process.

According to an embodiment of the present disclosure, in the manufacturing method of the capacitor structure, the capacitor may be further formed on the top surface of the stack structure.

According to an embodiment of the present disclosure, the manufacturing method of the capacitor structure may further include the following steps: forming a third dielectric layer between the capacitor and the substrate and between the capacitor and the stack structure; forming a fourth dielectric layer on the capacitor, and the fourth dielectric layer may be filled in the trench.

According to an embodiment of the present disclosure, in the manufacturing method of the capacitor structure, the first dielectric layer closest to the substrate may be located between the second dielectric layer closest to the substrate and the substrate.

According to an embodiment of the present disclosure, in the manufacturing method of the capacitor structure, the second dielectric layer closest to the substrate may be located between the first dielectric layer closest to the substrate and the substrate.

Based on the above, in the capacitor structure and the manufacturing method thereof provided by the present disclosure, the stack structure includes at least one first dielectric layer and at least one second dielectric layer alternately disposed on the substrate. There is a trench in the at least one first dielectric layer, the at least one second dielectric layer and the substrate. The trench has at least one recess on the at least one sidewall of the at least one first dielectric layer. The capacitor is disposed on the surface of the trench. Therefore, the capacitance value of the capacitor structure may be further improved and the process complexity of the capacitor structure may be reduced.

In order to make the above-mentioned features and advantages of the present disclosure more obvious and easy to understand, embodiments are given below and described in detail with reference to the attached drawings.

### BRIEF DESCRIPTION OF THE DRAWINGS

FIG. 1A to FIG. 1E are cross-sectional views of a manufacturing process of a capacitor structure according to some embodiments of the present disclosure.

FIG. 2 is a cross-sectional view of a capacitor structure according to other embodiments of the present disclosure.

### DESCRIPTION OF EMBODIMENTS

The embodiments are listed below and described in detail with reference to the accompanying drawings. However, the provided embodiments are not intended to limit the scope of the present disclosure. To facilitate understanding, the same components will be identified with the same symbols in the following description. In addition, the drawings are for illustrative purposes only and are not drawn to original size. In fact, the dimensions of the various features may be increased or reduced freely for clarity of discussion.

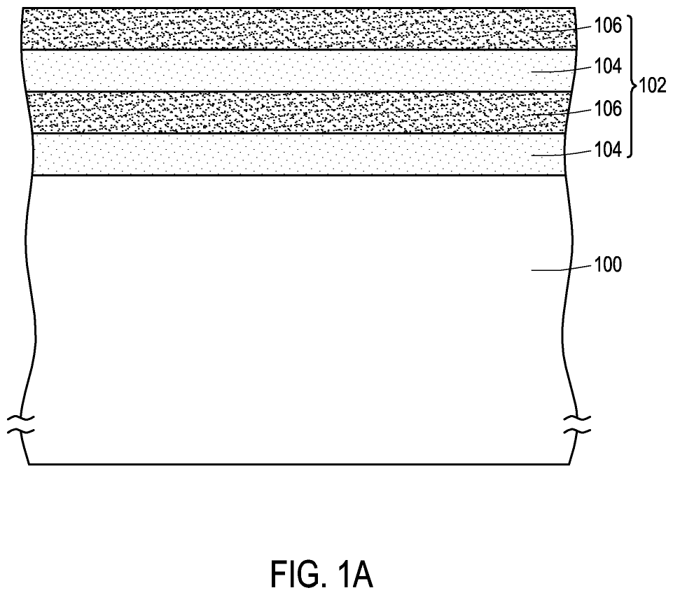

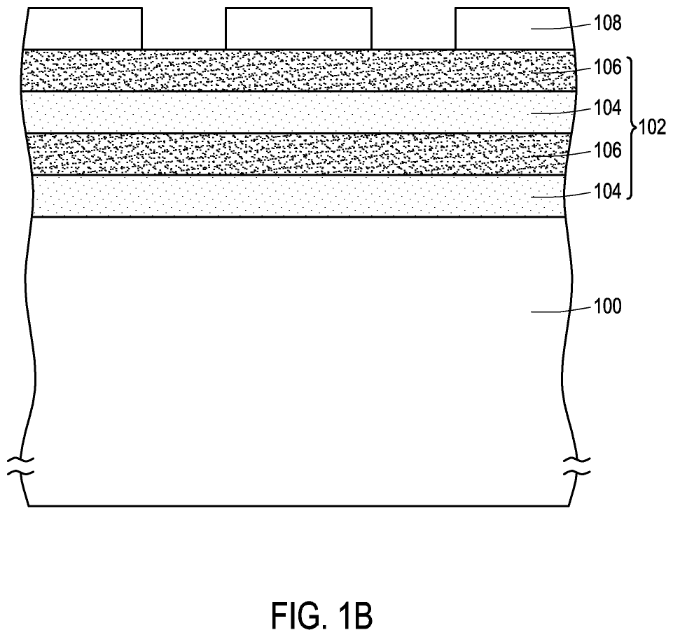

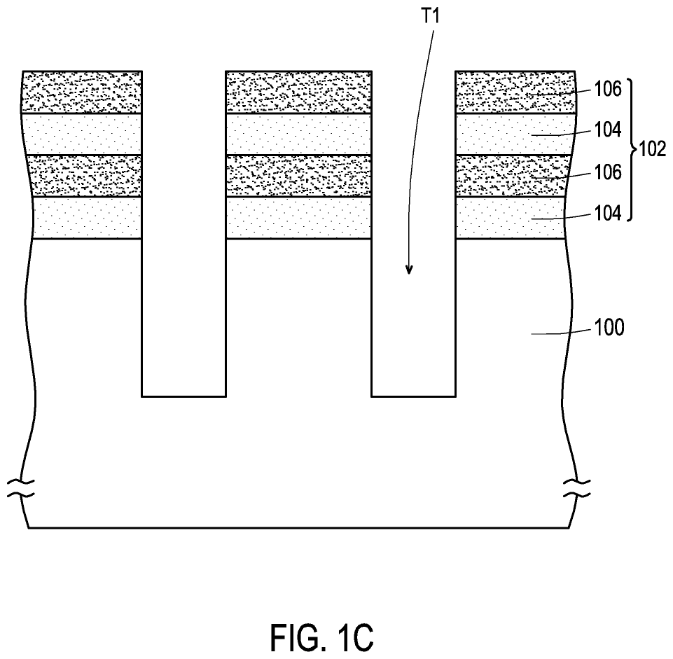

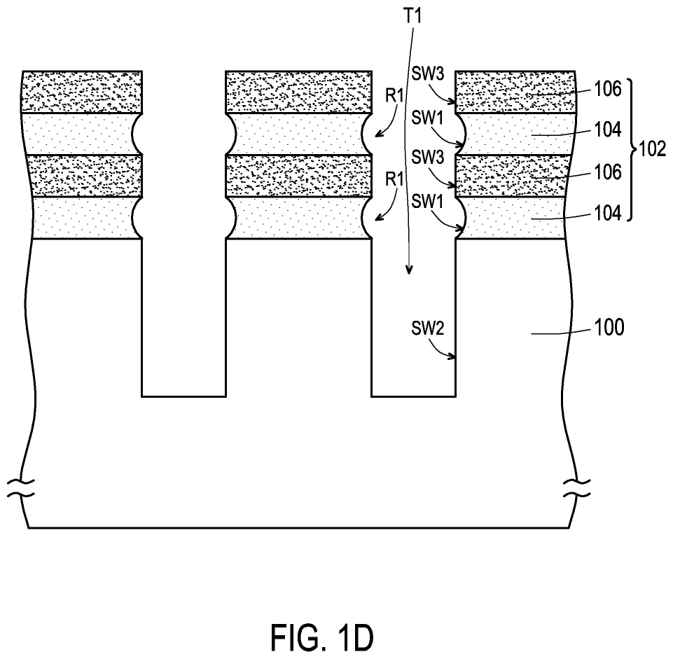

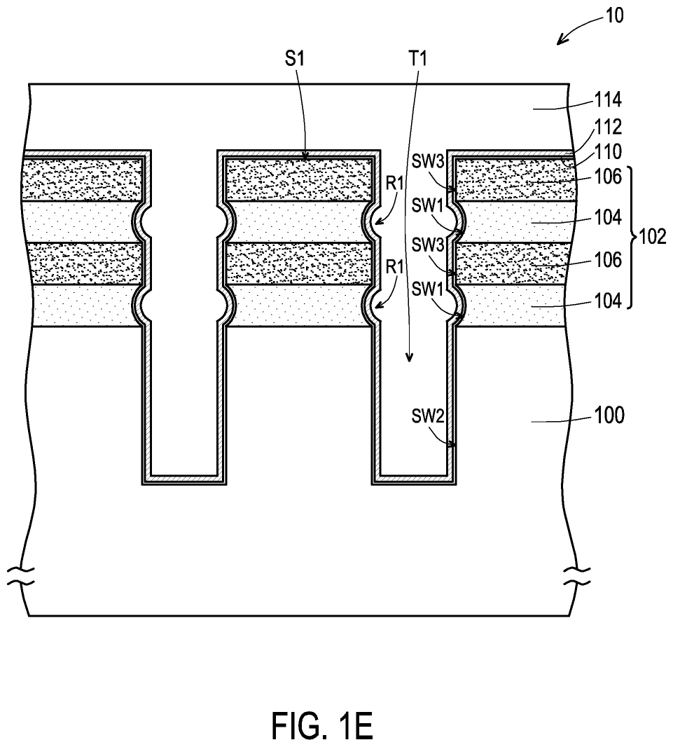

FIG. 1A to FIG. 1E are cross-sectional views of a manufacturing process of a capacitor structure according to some embodiments of the present disclosure.

Referring to FIG. 1A, a substrate 100 is provided. In some embodiments, the substrate 100 may be a semiconductor substrate, such as a silicon substrate.

Next, the stack structure 102 is formed. The stack structure 102 includes at least one dielectric layer 104 and at least one dielectric layer 106 alternately disposed on the substrate 100. In this embodiment, the dielectric layer 104 closest to the substrate 100 may be located between the dielectric layer 106 closest to the substrate 100 and the substrate 100, but the disclosure is not limited thereto. The material of the dielectric layer 104 and the material of the dielectric layer 106 may be different materials. In addition, in the same etching process, the dielectric layer 104 and the dielectric layer 106 may have different etching rates. In some embodiments, the material of the dielectric layer 104 is, for example, silicon oxide, silicon nitride, silicon oxynitride (SiON), or silicon nitride carbide (SiCN). In some embodiments, the dielectric layer 104 is formed through a chemical vapor deposition method, for example. In some embodiments, the material of the dielectric layer 106 is, for example, silicon oxide, silicon nitride, silicon oxynitride, or silicon nitride carbide. In some embodiments, the dielectric layer 106 is formed through a chemical vapor deposition method, for example. In this embodiment, the material of the dielectric layer 104 may be silicon oxide, and the material of the dielectric layer 106 may be silicon nitride, but the disclosure is not limited thereto.

In addition, the number of dielectric layers 104 and the number of dielectric layers 106 are not limited to the numbers shown in the figures. In this embodiment, the number of dielectric layers 104 and the number of dielectric layers 106 are exemplified as multiple, but the disclosure is not limited thereto. The circumstance where there are at least one dielectric layer 104 and at least one dielectric layer 106 included in the stack structure 102 belongs to the scope of the present disclosure.

Referring to FIG. 1B, a patterned photoresist layer 108 may be formed on the stack structure 102. The patterned photoresist layer 108 may expose a part of the stack structure 102. In some embodiments, the patterned photoresist layer 108 may be formed by a photolithography process.

Referring to FIG. 1C, the patterned photoresist layer 108 may be used as a mask to remove a part of the stack structure 102 and a part of the substrate 100 to form a trench T1. In this way, the trench T1 may be formed in the dielectric layer 104, the dielectric layer 106 and the substrate 100. In some embodiments, the trench T1 may be a deep trench. In some embodiments, a method for removing a part of the stack structure 102 and a part of the substrate 100 is, for example, dry etching.

After forming the trench T1, the patterned photoresist layer 108 may be removed. In some embodiments, the patterned photoresist layer 108 is removed by, for example, dry stripping or wet stripping.

Referring to FIG. 1D, an isotropic etching process may be performed on at least one dielectric layer 104 to form at least one recess R1. In this way, the trench T1 has at least one recess R1 on at least one sidewall SW1 of the at least one dielectric layer 104. In some embodiments, the cross-sectional contour of the at least one recess R1 may include a curved surface. In this embodiment, an isotropic etching process may be performed on all dielectric layers 104 to form multiple recesses R1, and the cross-sectional contours of all recesses R1 may include curved surfaces. In some embodiments, the isotropic etching process is, for example, a dry etching process or a wet etching process. In the isotropic etching process, the etching rate of the dielectric layer 104 may be greater than the etching rate of the dielectric layer 106 and the etching rate of the substrate 100.

In some embodiments, the trench T1 does not have a recess on the sidewall SW2 of the substrate 100. In some embodiments, the sidewall SW2 of the substrate 100 exposed by the trench T1 may be a flat surface. In some embodiments, the trench T1 does not have a recess on at least one sidewall SW3 of the at least one dielectric layer 106. In some embodiments, the at least one sidewall SW3 of the at least one dielectric layer 106 exposed by the trench T1 may be a flat surface. In this embodiment, the trench T1 does not have a recess on all sidewalls SW3 of all dielectric layers 106, and all sidewalls SW3 of all dielectric layers 106 exposed by the trench T1 may be flat surfaces.

Referring to FIG. 1E, a dielectric layer 110 may be formed on the surface of the trench T1 and the stack structure 102. In some embodiments, the material of the dielectric layer 110 is, for example, silicon oxide. In some embodiments, the dielectric layer 110 is formed through a chemical vapor deposition method or a physical vapor deposition method, for example.

Next, the capacitor 112 may be formed on the dielectric layer 110. In this way, the capacitor 112 may be formed on the surface of the trench T1. In addition, the capacitor 112 may be further formed on the top surface S1 of the stack structure 102. Through the above method, the dielectric layer 110 may be formed between the capacitor 112 and the substrate 100 and between the capacitor 112 and the stack structure 102. In some embodiments, the capacitor 112 may be a multi-layer structure. In some embodiments, the capacitor 112 may include a plurality of electrode layers (not shown) alternately stacked together and at least one insulating layer (not shown). In some embodiments, the material of the electrode layer is, for example, titanium (Ti), titanium nitride (TiN), tantalum (Ta), tantalum nitride (TaN), tungsten (W), cobalt (Co), or combinations thereof. In some embodiments, the electrode layer is formed through a chemical vapor deposition method, for example. In some embodiments, the material of the insulating layer is, for example, a high-k material, silicon oxide or silicon nitride. In some embodiments, the insulating layer is formed by a chemical vapor deposition method or an atomic layer deposition (ALD) method. In some embodiments, the capacitor 112 may be a metal layer/insulating layer/metal layer (MIM) capacitor, a metal layer/insulating layer/metal layer/insulating layer/metal layer (MIMIM) capacitor, or a metal layer/insulating layer/metal layer/insulating layer/metal layer/insulating layer/metal layer (MIMIMIM) capacitor and other capacitors.

Then, the dielectric layer 114 may be formed on the capacitor 112. The dielectric layer 114 may be filled in the trench T1. In some embodiments, the material of the dielectric layer 114 is, for example, silicon oxide. In some embodiments, the dielectric layer 114 is formed through a chemical vapor deposition method, for example.

Hereinafter, the capacitor structure 10 of the above embodiment will be described with reference to FIG. 1E. In addition, although the method for forming the capacitor structure 10 is described by taking the above method as an example, the present disclosure is not limited thereto.

Referring to FIG. 1E, the capacitor structure 10 includes the substrate 100, the stack structure 102 and the capacitor 112. The stack structure 102 includes at least one dielectric layer 104 and at least one dielectric layer 106 alternately disposed on the substrate 100. There is a trench T1 in the at least one dielectric layer 104, the at least one dielectric layer 106 and the substrate 100. The trench T1 has at least one recess R1 on the at least one sidewall SW1 of the at least one dielectric layer 104. The capacitor 112 is disposed on the surface of the trench T1. In some embodiments, the capacitor 112 may be further disposed on the top surface S1 of the stack structure 102.

The capacitor structure 10 may further include a dielectric layer 110 and a dielectric layer 114. The dielectric layer 110 is disposed between the capacitor 112 and the substrate 100 and between the capacitor 112 and the stack structure 102. The dielectric layer 114 is disposed on the capacitor 112. The dielectric layer 114 may be filled in the trench T1.

In addition, the details of various components in the capacitor structure 10 (such as materials and formation methods, etc.) have been described in detail in the above embodiments and will not be repeated.

Based on the above embodiments, it can be known that in the capacitor structure 10 and the manufacturing method thereof, the stack structure 102 includes at least one dielectric layer 104 and at least one dielectric layer 106 alternately disposed on the substrate 100. There is a trench T1 in the at least one dielectric layer 104, the at least one dielectric layer 106 and the substrate 100. The trench T1 has at least one recess R1 on the at least one sidewall SW1 of the at least one dielectric layer 104. The capacitor 112 is disposed on the surface of the trench T1. Therefore, the capacitance value of the capacitor structure 10 may be further improved and the process complexity of the capacitor structure 10 may be reduced.

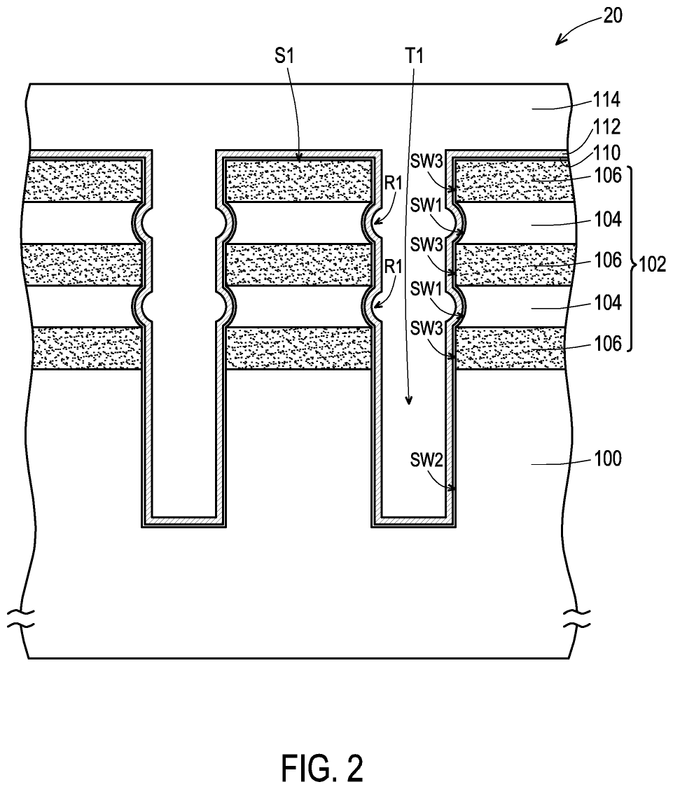

FIG. 2 is a cross-sectional view of a capacitor structure according to other embodiments of the present disclosure.

Please refer to FIG. 1E and FIG. 2. The difference between the capacitor structure 20 of FIG. 2 and the capacitor structure 10 of FIG. 1E is as follows. In the capacitor structure 20 of FIG. 2, the dielectric layer 106 closest to the substrate 100 may be located between the dielectric layer 104 closest to the substrate 100 and the substrate 100. In the manufacturing method of the capacitor structure 10 in FIG. 1E, the dielectric layer 104 closest to the substrate 100 may be formed first on the substrate 100, and then the dielectric layer 106 closest to the substrate 100 may be formed on the dielectric layer 104 closest to the substrate 100. In the manufacturing method of the capacitor structure 20 in FIG. 2, the dielectric layer 106 closest to the substrate 100 may be formed first on the substrate 100, and then the dielectric layer 104 closest to the substrate 100 may be formed on the dielectric layer 106 closest to the substrate 100. In addition, the remaining steps of the manufacturing method of the capacitor structure 20 in FIG. 2 may be derived from the manufacturing method of the capacitor structure 10 in FIG. 1E, and related description is omitted here. Moreover, in FIG. 1E and FIG. 2, the same or similar components are represented by the same symbols, and related description is omitted.

Based on the above embodiments, it can be known that in the capacitor structure 20 and the manufacturing method thereof, the stack structure 102 includes at least one dielectric layer 104 and at least one dielectric layer 106 alternately disposed on the substrate 100. There is a trench T1 in the at least one dielectric layer 104, the at least one dielectric layer 106 and the substrate 100. The trench T1 has at least one recess R1 on at least one sidewall SW1 of the at least one dielectric layer 104. The capacitor 112 is disposed on the surface of the trench T1. Therefore, the capacitance value of the capacitor structure 20 may be further improved and the process complexity of the capacitor structure 20 may be reduced.

To sum up, in the capacitor structure and the manufacturing method thereof provided in the above embodiments, the stack structure includes at least one first dielectric layer and at least one second dielectric layer alternately disposed on the substrate. There is a trench in the at least one first dielectric layer, the at least one second dielectric layer and the substrate. The trench has at least one recess on the at least one sidewall of the at least one first dielectric layer. The capacitor is disposed on the surface of the trench. Therefore, the capacitance value of the capacitor structure may be further improved and the process complexity of the capacitor structure may be reduced.

Although the present disclosure has been disclosed above through embodiments, it is not intended to limit the present disclosure. Anyone with ordinary knowledge in the technical field can make some modifications and refinement without departing from the spirit and scope of the present disclosure. Therefore, the protection scope of the present disclosure shall be determined by the appended claims.

What is claimed is:

1. A capacitor structure, comprising:
a substrate;
a stack structure comprising at least one first dielectric layer and at least one second dielectric layer alternately disposed on the substrate, wherein there is a trench in the at least one first dielectric layer, the at least one second dielectric layer and the substrate, and the trench has at least one recess on at least one sidewall of the at least one first dielectric layer; and
a capacitor disposed on a surface of the trench.

2. The capacitor structure according to claim 1, wherein a cross-sectional contour of the at least one recess comprises a curved surface.

3. The capacitor structure according to claim 1, wherein the trench does not have a recess on a sidewall of the substrate.

4. The capacitor structure according to claim 1, wherein a sidewall of the substrate exposed by the trench is a flat surface.

5. The capacitor structure according to claim 1, wherein the trench does not have a recess on at least one sidewall of the at least one second dielectric layer.

6. The capacitor structure according to claim 1, wherein at least one sidewall of the at least one second dielectric layer exposed by the trench is a flat surface.

7. The capacitor structure according to claim 1, wherein the first dielectric layer closest to the substrate is located between the second dielectric layer closest to the substrate and the substrate.

8. The capacitor structure according to claim 1, wherein the second dielectric layer closest to the substrate is located between the first dielectric layer closest to the substrate and the substrate.

9. The capacitor structure according to claim 1, wherein the capacitor is further disposed on a top surface of the stack structure.

10. The capacitor structure according to claim 1, further comprising:
a third dielectric layer disposed between the capacitor and the substrate and between the capacitor and the stack structure; and
a fourth dielectric layer disposed on the capacitor and filled in the trench.

11. A manufacturing method of a capacitor structure, comprising:
providing a substrate;
forming a stack structure, wherein the stack structure comprises at least one first dielectric layer and at least one second dielectric layer alternately disposed on the substrate;
forming a trench in the at least one first dielectric layer, the at least one second dielectric layer, and the substrate, wherein the trench has at least one recess on at least one sidewall of the at least one first dielectric layer; and
forming a capacitor on a surface of the trench.

12. The manufacturing method of the capacitor structure according to claim 11, wherein the method for forming the trench comprises:
forming a patterned photoresist layer on the stack structure; and
using the patterned photoresist layer as a mask to remove a part of the stack structure and a part of the substrate to form the trench.

13. The manufacturing method of the capacitor structure according to claim 12, wherein the method for removing the part of the stack structure and the part of the substrate comprises dry etching.

14. The manufacturing method of the capacitor structure according to claim 12, further comprising:
removing the patterned photoresist layer after forming the trench.

15. The manufacturing method of the capacitor structure according to claim 14, wherein the method of forming the at least one recess comprises:
performing an isotropic etching process on the at least one first dielectric layer to form the at least one recess.

16. The manufacturing method of the capacitor structure according to claim 15, wherein the isotropic etching process comprises a dry etching process or a wet etching process.

17. The manufacturing method of the capacitor structure according to claim 11, wherein the capacitor is further formed on a top surface of the stack structure.

18. The manufacturing method of the capacitor structure according to claim 11, further comprising:
forming a third dielectric layer between the capacitor and the substrate and between the capacitor and the stack structure; and
forming a fourth dielectric layer on the capacitor, wherein the fourth dielectric layer is filled in the trench.

19. The manufacturing method of the capacitor structure according to claim 11, wherein the first dielectric layer closest to the substrate is located between the second dielectric layer closest to the substrate and the substrate.

20. The manufacturing method of the capacitor structure according to claim 11, wherein the second dielectric layer closest to the substrate is located between the first dielectric layer closest to the substrate and the substrate.
